(19) United States
(12) Patent Application Publication
(10) Pub. No.: US 2010/0300732 A1
(43) Pub. Date: Dec. 2, 2010

(54) MULTI-LAYER PRINTED CIRCUIT BOARD

(75) Inventor: QI-JIE CHEN, Shenzhen City (CN)

Correspondence Address: Altis Law Group, Inc.;ATTN: Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/511,286

(22) Filed: Jul. 29, 2009

(30) Foreign Application Priority Data
May 27, 2009 (CN) 200910302687.3

(51) Int. Cl. H05K 1/02

(52) U.S. Cl. 174/255

(57) ABSTRACT

A multi-layer printed circuit board includes a first trace layer and a second trace layer. The second trace layer and the first trace layer are located on parallel horizontal planes. A first group of traces is laid on the first trace layer. A second group of traces is laid on the second trace layer. The second group of traces and the first group of traces are positioned on up and down positions of the first trace layer and the second trace layer. The first group of traces and the second group of traces extend in different directions.

### BACKGROUND

1. Technical Field

The present embodiment relates to a circuit board and particularly to a multi-layer printed circuit board.

2. Description of Related Art

Electronic products, such as notebook computers and smart phones, become more and more compact. For reducing size of the electronic products, multi-layer printed circuit boards (PCBs) are widely used to integrate more electronic elements thereon.

At present, the multi-layer PCB includes 4-layer, 6-layer, and even up to 10-layer PCB, and so on. The conventional 4-layer PCB includes two trace layers, a ground layer, and a power source layer. The trace layer, the ground layer, and the power source layer are separated by insulating layers. The power source layer is used to provide different voltages to drive electronic elements mounted on the PCB. The trace layer is used to lay traces thereon. However, the traces laid on different trace layers often generate cross-talk, especially when these traces are located on up and down positions of the trace layers. The cross talk greatly influences quality of the signals transmitted through the traces.

Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of an embodiment of a multi-layer printed circuit board;

FIG. 2 is another schematic view of the multi-layer printed circuit board of FIG. 1; and

FIG. 3 is another schematic view of the multi-layer printed circuit board of FIG. 1.

### DETAILED DESCRIPTION

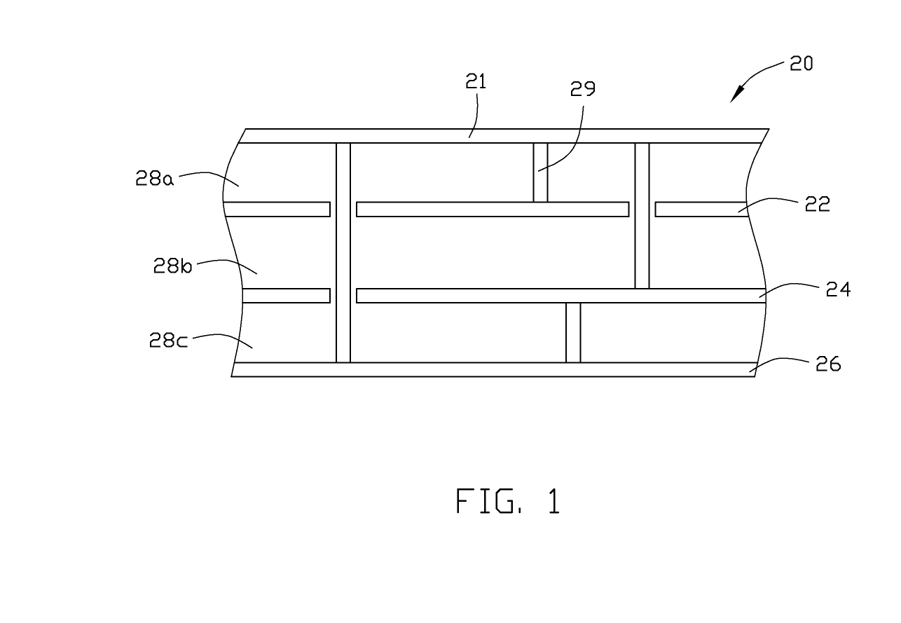

Referring to FIG. 1, a multi-layer printed circuit board 20 in accordance with an embodiment includes a first trace layer 21, a second trace layer 26, a ground layer 22, a power source layer 24, and a plurality of insulating layers 28a, 28b, and 28c. These layers are located on different parallel horizontal planes. The power source layer 24 provides different voltages for the PCB 20. The insulating layers 28a, 28b, and 28c are used to separate the trace layers 21, 26, the ground layer 22, and the power source layer 24. A plurality of conductive perforations 29 is defined in the PCB 20 to connect different layers to each other.

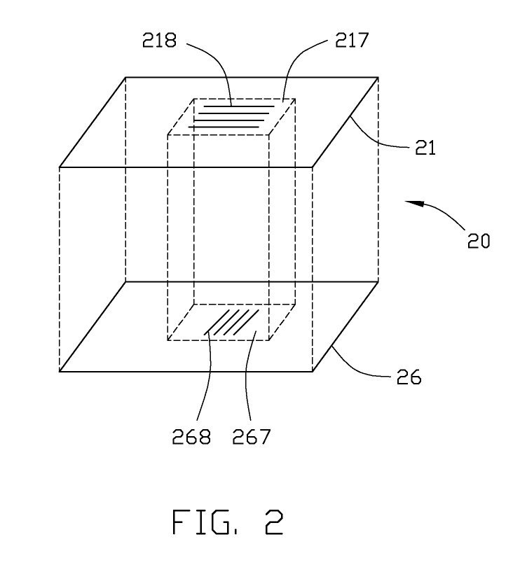

Referring to FIG. 2, a schematic view of the first trace layer 21 and the second trace layer 26 is shown. The first trace layer 21 defines a first region 217. A first group of signal traces 218 are laid in the first region 217. The second trace layer 26 defines a second region 267, which coincides with an orthographic projection of the first region 217 on the second trace layer 26. A second group of signal traces 268 are laid in the second region 267. The first group of signal traces 218 are set at approximately a 90 degree angle to the direction of the second group of signal traces 268. By laying the first group of signal traces 218 and the second group of signal traces 268 in this manner, cross talk between the first group of traces 218 and the second group of traces 268 is minimized because they only cross each other and do not follow similar paths, which can improve the quality of signal transmission through the traces 218 and 268.

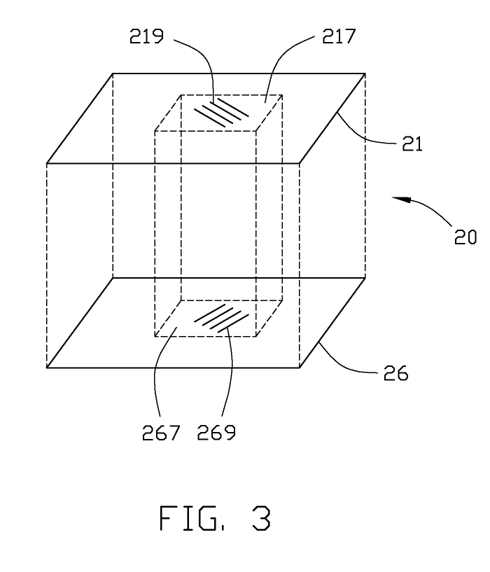

Referring to FIG. 3, another schematic view of the first trace layer 21 and the second trace layer 26 is shown. A third group of signal traces 219 are laid in the first region 217. A fourth group of signal traces 269 are laid in the second region 267. The third group of signal traces 219 and the fourth group of signal traces 269 extend in different directions. Therefore, an orthographic projection of the third group of signal traces 219 onto the second trace layer 26 crosses the fourth group of signal traces 269 at angle not equal to zero degrees. By laying the third group of signal traces 219 and the fourth group of signal traces 269 in this manner, cross talk between the third group of traces 219 and the fourth group of traces 269 can be minimized as well. The greater the angle between the third group of signal traces 219 and the fourth group of signal traces 269, the less cross talk between the third group of traces 219 and the fourth group of traces 269.

It is to be understood, however, that even though numerous characteristics and advantages of the embodiments have been set forth in the foregoing description, together with details of the structure and function of the embodiments, the disclosure is illustrative only, and changes may be made in detail, especially in matters of shape, size, and arrangement of parts within the principles of the present disclosure to the full extent indicated by the broad general meaning of the terms in which the appended claims are expressed.

What is claimed is:

1. A multi-layer printed circuit board, comprising:
a first trace layer, a first group of traces laid on the first trace layer; and
a second trace layer, the second trace layer and the first trace layer located on parallel horizontal planes, a second group of traces laid on the second trace layer; the second group of traces and the first group of traces positioned on up and down positions of the first trace layer and the second trace layer, the first group of traces and the second group of traces extending in different directions.

2. The printed circuit board of claim 1, wherein the second trace layer is parallel with the first trace layer.

3. The printed circuit board of claim 2, wherein the first trace layer defines a first region, the first group of signal traces are located in the first region; the second trace layer defines a second region, the second group of signal traces are located in the second region, the second region coincides with an orthographic projection of the first region on the second trace layer.

4. The printed circuit board of claim 3, wherein the first group of traces is perpendicular to the second group of traces.

5. The printed circuit board of claim 1, further comprising a power source layer capable of providing different voltage power to the printed circuit board.

6. The printed circuit board of claim 5, wherein a plurality of insulating layers is located between the first trace layer, the second trace layer and the power source layer.

7. The printed circuit board of claim 6, wherein a plurality of conductive perforations is defined in the printed circuit board to allow communication between the first trace layer, the second trace layer, the power source layer and combinations thereof.

8. A multi-layer printed circuit board, comprising:
a first trace layer, a first group of traces located on the first trace layer; and
a second trace layer, a second group of traces located on the second trace layer, an orthographic projection of the first group of signal traces on the second trace layer crossing the second group of signal trace at angle not equal to zero degrees.

9. The multi-layer printed circuit board of claim 8, wherein the first and second trace layers are located on parallel horizontal planes.

10. The printed circuit board of claim 9, wherein the first trace layer defines a first region, the first group of signal traces are located in the first region, the second trace layer defines a second region, the second group of signal traces are located in the second region, the second region coincides with an orthographic projection of the first region on the second trace layer.

11. The printed circuit board of claim 10, wherein the first group of traces is parallel with an edge of the first trace layer, and the second group of traces is parallel with an edge of the second trace layer.

12. The printed circuit board of claim 10, wherein the first group of traces is perpendicular to the second group of traces.

13. The printed circuit board of claim 8, further comprising a power source layer capable of providing different voltage power to the printed circuit board.

14. The printed circuit board of claim 13, wherein a plurality of insulating layers is located between the first trace layer, the second trace layer and the power source layer.

15. The printed circuit board of claim 14, wherein a plurality of conductive perforations is defined in the printed circuit board to allow communication between the first trace layer, the second trace layer, the power source layer and combinations thereof.
